(19) United States
(12) Patent Application Publication
(10) Pub. No.: US 2026/0349022 A1
(43) Pub. Date: Nov. 5, 2026

(54) METHODS AND SYSTEMS FOR MONITORING WIRELESS SENSORS

(71) Applicant: Ohio State Innovation Foundation, Columbus, OH (US)

(72) Inventors: Jinghua LI, Columbus, OH (US); Tzu-Li LIU, Columbus, OH (US)

(21) Appl. No.: 19/119,992

(22) PCT Filed: Oct. 10, 2023
(86) PCT No.: PCT/US2023/034806

§ 371 Date: Apr. 10, 2025

Related U.S. Application Data
(60) Provisional application No. 63/414,625, filed on Oct. 10, 2022.

(51) Int. Cl. G01R 31/28; G01R 27/06; G01R 27/32

(52) U.S. Cl. CPC G01R 31/2829; G01R 27/06; G01R 27/32

(57) ABSTRACT

An example device for measuring a response of a sensor is described herein. The device includes a clock generator configured to transmit a radiofrequency (RF) signal; an antenna operably connected to the clock generator; a directional coupler configured to separate the RF signal into an incident wave and a reflected wave; a peak detector operably connected to the directional coupler; and a microcontroller operably connected to the peak detector, where the microcontroller is configured to measure an output of the peak detector.

### CROSS-REFERENCE TO RELATED APPLICATIONS

This application claims the benefit of U.S. provisional patent application No. 63/414,625, filed on Oct. 10, 2022, and titled “METHODS AND SYSTEMS MONITORING WIRELESS SENSORS,” the disclosure of which is expressly incorporated herein by reference in its entirety.

### BACKGROUND

Network analyzers can be used as part of design and/or testing of network devices. For example, a vector network analyzer can be used to analyze the response of electrical components (e.g., sensors) that are transmitting and/or receiving electromagnetic radiation. Network analyzers can be expensive and/or bulky and therefore difficult to use routinely. Therefore there is a need for systems and methods for sensing and/or tracing sensors.

### SUMMARY

Methods and systems for monitoring the response of a sensor are disclosed herein.

In some aspects, the techniques described herein relate to a device for measuring a response of a sensor, including: a clock generator configured to transmit a radiofrequency (RF) signal; an antenna operably connected to the clock generator; a directional coupler configured to separate the RF signal into an incident wave and a reflected wave; a peak detector operably connected to the directional coupler; and a microcontroller operably connected to the peak detector, wherein the microcontroller is configured to measure an output of the peak detector.

In some aspects, the techniques described herein relate to a device, wherein the microcontroller includes a wireless transceiver, wherein the microcontroller is configured to transmit, using the wireless transceiver, a signal based on a signal received from the peak detector to a remote device.

In some aspects, the techniques described herein relate to a device, wherein the directional coupler includes a standing wave ratio bridge.

In some aspects, the techniques described herein relate to a device, wherein the peak detector is configured to output a DC voltage correlated to an RF power of a signal received from the directional coupler.

In some aspects, the techniques described herein relate to a device, wherein the microcontroller is configured to output a resonance frequency of the sensor.

In some aspects, the techniques described herein relate to a device, wherein the microcontroller is configured to output an impedance of the sensor.

In some aspects, the techniques described herein relate to a device, wherein the microcontroller is configured to output a phase delay of the sensor.

In some aspects, the techniques described herein relate to a device, wherein the microcontroller is configured to output a reflection coefficient of the sensor.

In some aspects, the techniques described herein relate to a device, wherein the microcontroller is configured to output a transmission coefficient of the sensor.

In some aspects, the techniques described herein relate to a device, wherein the microcontroller is configured to output a Q-factor of the sensor.

In some aspects, the techniques described herein relate to a device, wherein the microcontroller further includes an analog to digital converter and the peak detector is operably coupled to the microcontroller via the analog to digital converter.

In some aspects, the techniques described herein relate to a device, wherein the microcontroller is operably connected to the clock generator.

In some aspects, the techniques described herein relate to a device, wherein the sensor is an inductor-resistor-capacitor (LRC) sensor.

In some aspects, the techniques described herein relate to a device, wherein the device is a portable device.

In some aspects, the techniques described herein relate to a system for measuring a response of a sensor, including: a clock generator configured to transmit a radiofrequency (RF) signal; an antenna operably connected to the clock generator; a directional coupler configured to separate the RF signal into an incident wave and a reflected wave; a peak detector operably connected to the directional coupler; and a computing device in operable communication with the peak detector, wherein the computing device includes a processor and a memory, the memory having computer-executable instructions stored thereon that, when executed by the processor, cause the processor to: measure an output of the peak detector.

In some aspects, the techniques described herein relate to a system, wherein the system further includes a wireless transceiver, wherein the memory has further computer-executable instructions stored thereon that, when executed by the processor, cause the processor to transmit, using the wireless transceiver, a signal based on a signal received from the peak detector to a remote device.

In some aspects, the techniques described herein relate to a system, wherein the directional coupler includes a standing wave ratio bridge.

In some aspects, the techniques described herein relate to a system, wherein the peak detector is configured to output a DC voltage correlated to an RF power of a signal received from the directional coupler.

In some aspects, the techniques described herein relate to a system any one, wherein the computing device is configured to output a resonant frequency of the sensor.

In some aspects, the techniques described herein relate to a system any one, wherein the computing device is configured to output an impedance of the sensor.

In some aspects, the techniques described herein relate to a system any one, wherein the computing device is configured to output a return loss of the sensor.

In some aspects, the techniques described herein relate to a system, wherein the computing device further includes an analog to digital converter and the peak detector is operably coupled to the computing device via the analog to digital converter.

In some aspects, the techniques described herein relate to a system, wherein the computing device is operably connected to the clock generator.

In some aspects, the techniques described herein relate to a system, wherein the sensor is configured to monitor properties including, but not limited to, phase delay, reflection and transmission coefficients, resonance frequency, Q-factor, and impedance.

In some aspects, the techniques described herein relate to a system, wherein the sensor is an inductor-resistor-capacitor (LRC) sensor.

In some aspects, the techniques described herein relate to a system, wherein the system is a portable device.

In some aspects, the techniques described herein relate to a system, wherein the system is a miniaturized wired device.

It should be understood that the above-described subject matter may also be implemented as a computer-controlled apparatus, a computer process, a computing system, or an article of manufacture, such as a computer-readable storage medium.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1 illustrates a system including a sensor, readout circuit, and display, according to implementations of the present disclosure.

FIG. 2 is an example computing device.

FIG. 3A illustrates an example plot of S11 vs. frequency for an example implementation of the present disclosure.

FIG. 3B illustrates an example plot of resonant frequency (fs) vs potential for an example implementation of the present disclosure.

FIG. 4 illustrates a schematic including a readout circuit and LC sensor, according to an implementation of the present disclosure.

FIG. 5 illustrates an antenna, peak detector, SWR bridge, and clock generator, according to an implementation of the present disclosure.

FIG. 6A illustrates a circuit board including an RF scanning circuit, LRC sensor, and wireless module, according to an implementation of the present disclosure.

FIG. 6B illustrates the circuit board shown in FIG. 6A with a user interface, according to an implementation of the present disclosure.

FIG. 7A illustrates an example plot of S11 vs. frequency for an example implementation of the present disclosure.

FIG. 7B illustrates an example plot of resonant frequency (fs) vs potential for an example implementation of the present disclosure.

FIG. 8A illustrates a perspective view of a readout circuit according to an example implementation of the present disclosure.

FIG. 8B illustrates a back view of the readout circuit shown in FIG. 8A.

FIG. 8C illustrates a front view of the readout circuit shown in FIG. 8A.

FIG. 8D illustrates a view of a PCB, battery, and antenna used in the readout circuit shown in FIGS. 8A-8D.

FIG. 9A illustrates a user interface showing that the display is connected to the reader according to an example implementation of the present disclosure.

FIG. 9B illustrates a user interface receiving data from the reader, according to an example implementation of the present disclosure.

FIG. 9C illustrates a user interface for data storage, according to an example implementation of the present disclosure.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. While implementations will be described for tracking or monitoring LRC-based wireless sensors, it will become evident to those skilled in the art that the implementations are not limited thereto, but are applicable for measuring and/or tracking any sensor that emits electromagnetic radiation. This may include, but is not limited to, a consumer device such as a health accessory used to track clinical vitals or health status of a subject.

Described herein are systems and methods for tracking and/or measuring the response of wireless sensors. Non-limiting examples of wireless sensors include LRC-based wireless sensors.

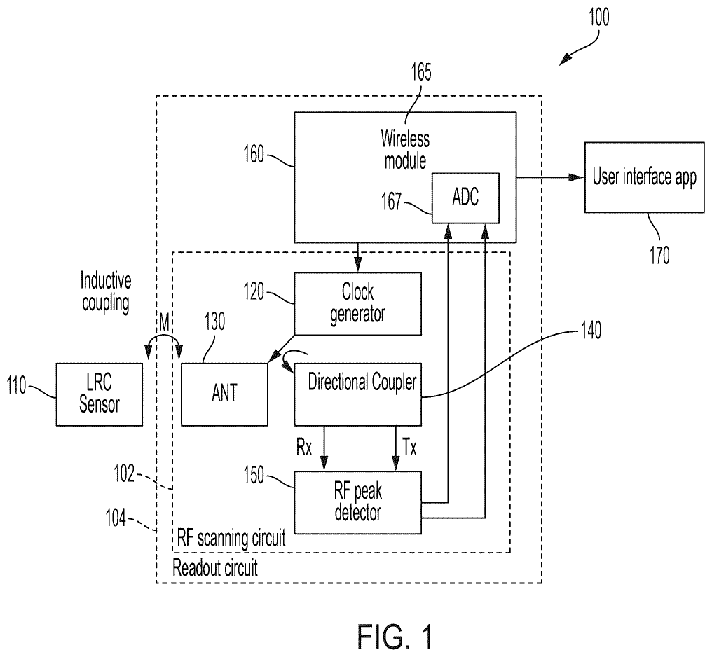

With reference to FIG. 1, an example system 100 is shown according to implementations of the present disclosure. The system 100 can include a readout circuit 104 that can perform tracing of LRC-based sensors. The readout circuit 104 described herein can be configured for both frequency and amplitude modulation. For example, the readout circuit 104 can detect resonant frequencies and/or peak amplitudes of LRC-based sensors. Alternatively or additionally, the readout circuit 104 can detect the impedance of LRC-based sensors.

Optionally, the readout circuit 104 is a portable readout circuit. The portable readout circuit can be simpler, lighter and/or cheaper than a conventional vector network analyzer (VNA). It should also be understood that the readout circuit 104 can be implemented as a miniaturized wireless device. Optionally, implementations of the present disclosure can be used as part of wearable or embedded systems where size, weight, and/or cost can be limitations. The collected data can be transmitted from the readout circuit to a user interface (e.g. cell phone, laptop, etc.). The readout circuit and user device described herein can be coupled through one or more communication links. This disclosure contemplates the communication links are any suitable communication link. For example, a communication link may be implemented by any medium that facilitates data exchange between the network elements including, but not limited to, wired, wireless and optical links. In the examples described herein, the communication link is a wireless communication link (e.g., low power wireless such as Bluetooth or near field communication (NFC)).

Still with reference to FIG. 1, the example system 100 can be used to monitor the response of an inductor-resistor-capacitor sensor (“LRC sensor”) 110. An example LRC-based sensor can be a wearable or embedded sensor configured to measure the health of a human. For example, measuring the response can include identifying the sensor's resonance frequency and return loss wirelessly. As another example, measuring the response can include identifying the sensor's impedance. It should be understood that, in some implementations of the present disclosure, the sensor's impedance can include the Q-factor of the sensor.

The readout circuit 104 can further include an RF scanning circuit 102. The RF scanning circuit can include an antenna 130, a directional coupler 140, a peak detector 150, and a clock generator 120. The RF scanning circuit 102 can be configured to sweep a range of frequencies and output the range of frequencies from the antenna 130. Optionally, the clock generator 120 is controlled by the microcontroller 160 to sweep the range of frequencies. The antenna 130 can output a swept frequency and collect a return signal. If the return signal is a wave, the system (e.g., the microcontroller 160) can determine the resonant frequency and/or Q factor of the LRC sensor 110. As described herein, the clock generator 120 can transmit radio frequencies into an antenna 130 and the radio frequencies can include a range of radio frequencies.

A directional coupler 140 can separate the RF signal into an incident wave and a reflected wave. As a non-limiting example, the directional coupler 140 can include a standing wave reflector (SWR) bridge, which can optionally be a 20 db SWR Bridge, as illustrated in FIG. 1. It should be understood that a 20 db SWR Bridge is provided only as an example. This disclosure contemplates using directional couplers other than SWR bridges and/or 20 dB SWR bridges.

The peak detector 150 can be operably coupled to the directional coupler 140. The peak detector 150 can detect the radiofrequency power and output a signal representing the amplitude of the radiofrequency power. Optionally, the signal can be directly correlated to the amplitude of the radiofrequency power.

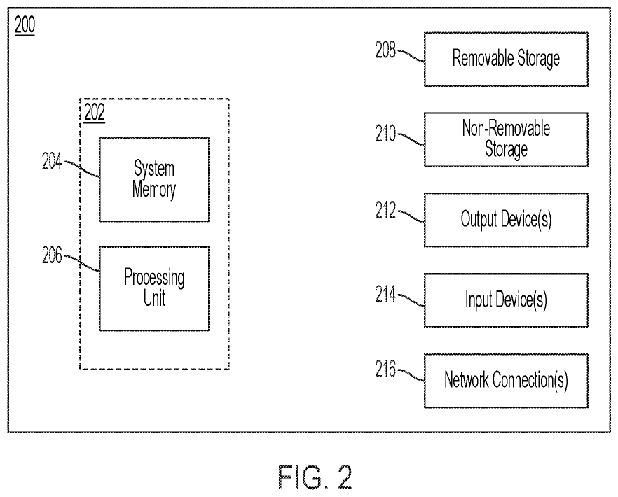

The peak detector 150 can be operably coupled to a microcontroller 160 so that the signal(s) output by the peak detector are input to the microcontroller. Optionally, the peak detector 150 is configured to output a DC signal and/or a digital signal to the microcontroller 160. The microcontroller 160 includes at least a processor and a memory (e.g., at least the basic configuration illustrated in FIG. 2 by dashed line 202). Optionally, the microcontroller 160 can include any or all of the components illustrated and described with reference to the computing device 200 illustrated in FIG. 2.

The microcontroller can be configured to measure the output of the peak detector. In some implementations, the microcontroller 160 can include an analog to digital converter (ADC) 167, which can be configured to receive signal(s) from the peak detector and convert the received signals into digital information. The ADC can optionally be a 14 bit ADC, as illustrated in FIG. 1. It should be understood that a 14 bit ADC is provided only as an example. This disclosure contemplates using ADCs other than 14 bit ADC shown in the figure.

In some implementations, the microcontroller 160 can include a wireless module 165 that can be used to transmit a DC voltage to a user interface 170 for display (e.g., the network connections 216 described with reference to FIG. 2). The user interface 170 can be part of another computing device (e.g., the computing device 200 illustrated in FIG. 2, and/or a personal computer). Optionally, the user interface 170 can be located on a remote device and/or on a portable device (e.g., smartphones, personal/laptop computers). The user interface 170 can include a display, where the display can include any of the components described with respect to the output device 212 described with reference to FIG. 2. The user interface 170 can be configured to display a resonant frequency of a sensor that is measured using the readout circuit 104.

The microcontroller 160 can use any type of wireless communication. Optionally, the microcontroller 160 can include a wireless module 165 operably coupled to the microcontroller 160 and capable of wireless communication. Non-limiting examples of wireless communication that can be used include Bluetooth, NFC, and WiFi.

In some implementations, the microcontroller 160 is operably connected to the clock generator 120.

In some implementations, the microcontroller 160 is configured to output the return loss of the sensor and/or the resonant frequency of the sensor. Optionally, the output of the microcontroller 160 is from the wireless module 165.

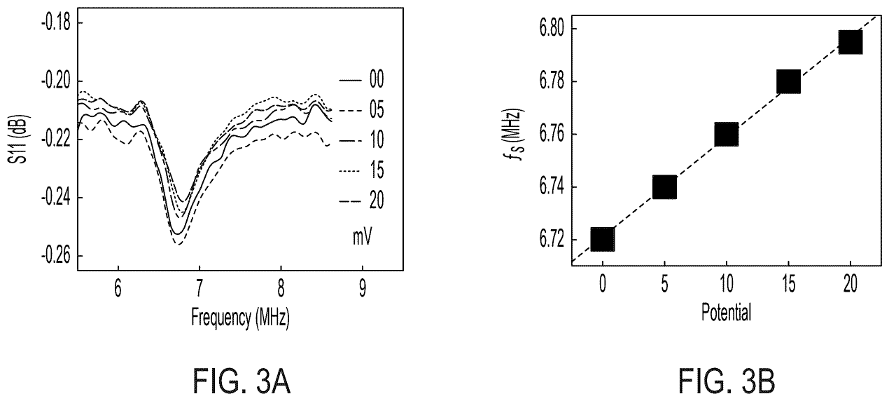

A study was performed, and experimental results are illustrated in FIGS. 3A-3B. FIG. 3A illustrates an example plot of S11 vs. frequency for an example implementation of the present disclosure. FIG. 3B illustrates an example plot of resonant frequency (fs) vs potential for an example implementation of the present disclosure.

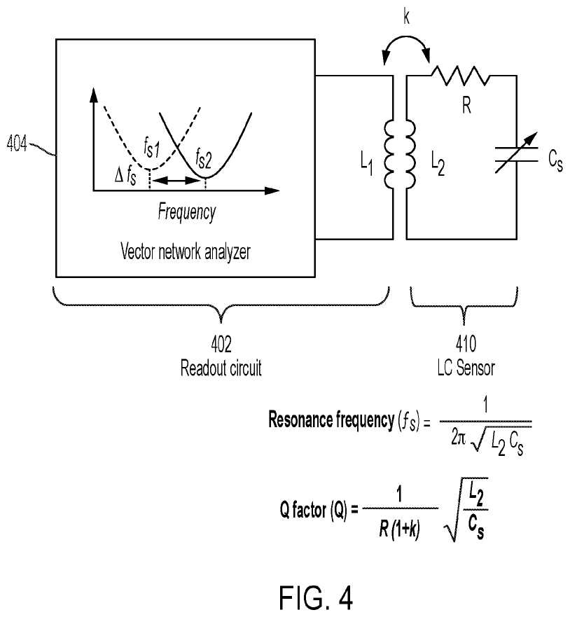

FIG. 4 illustrates a schematic including a readout circuit 402 using a vector network analyzer 404 and an LC sensor 410, according to an implementation of the present disclosure.

### Examples

Implementations of the present disclosure can include lightweight and/or miniaturized devices for tracking and/or measuring electrical signals. As non-limiting examples, implementations of the present disclosure can be used in consumer devices, health accessories, embedded devices, and wearable devices. Implementations of the present disclosure can be used to track clinical vital signs and health status on the skin.

### Example 1

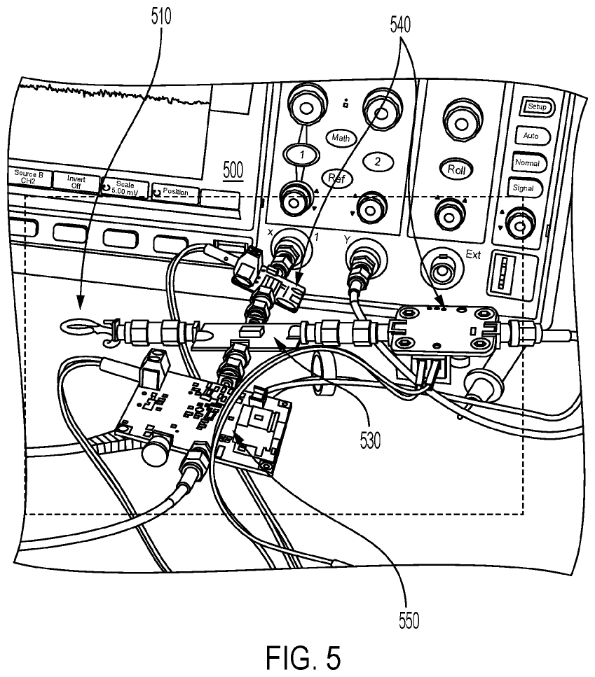

FIG. 5 illustrates an example implementation of the present disclosure 500 that was designed and tested. The example implementation shown in FIG. 5 includes an antenna 510, a peak detector 540, SWR bridge 530 and clock generator 550.

### Example 2

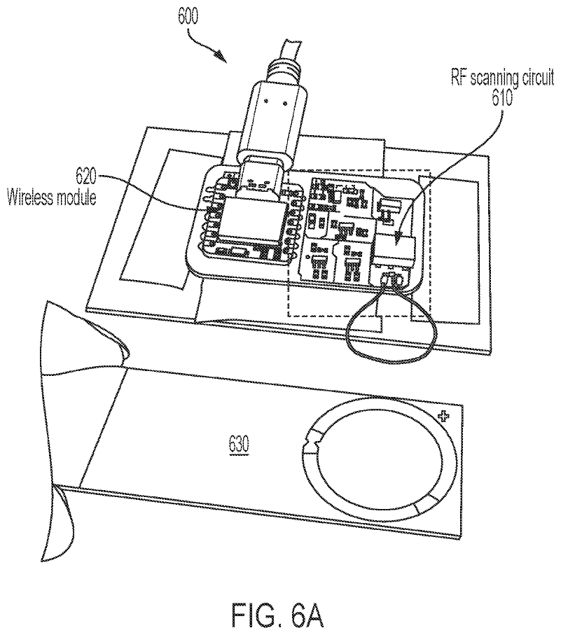

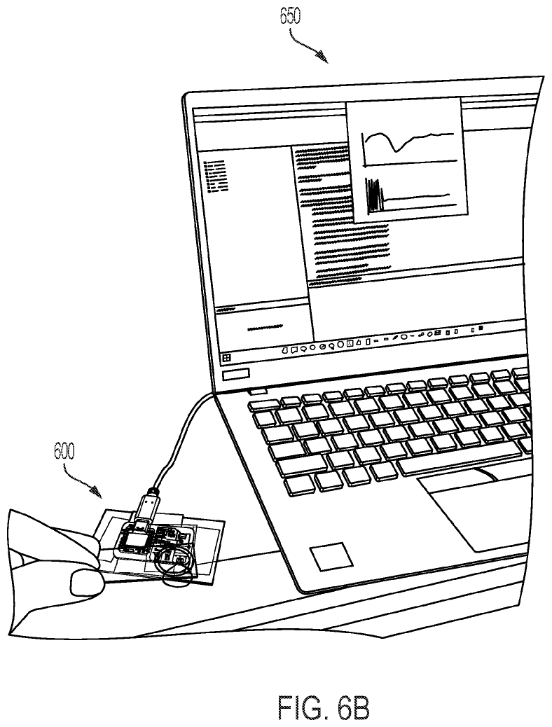

FIGS. 6A-6B illustrate an example implementation of the present disclosure that was designed and tested. FIG. 6A illustrates a circuit board 600 including an RF scanning circuit 610 and wireless module 620, according to an implementation of the present disclosure. FIG. 6A further illustrates an LRC sensor 630 that can be read using the RF scanning circuit.

FIG. 6B illustrates the circuit board 600 shown in FIG. 6A operably connected to a user interface 650, according to an implementation of the present disclosure.

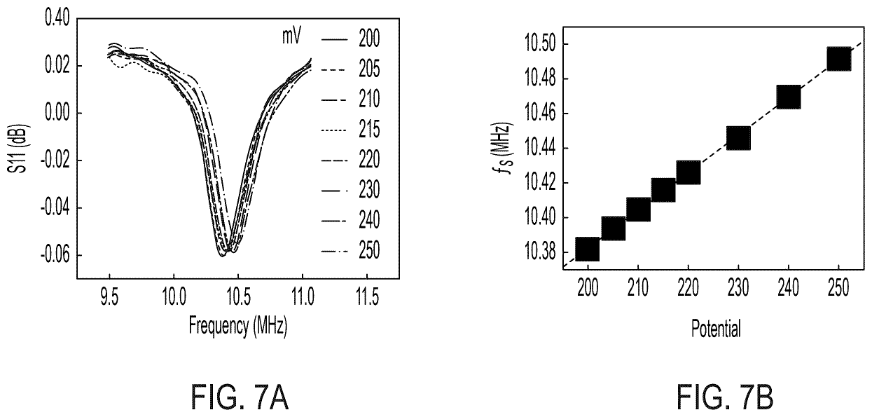

FIG. 7A illustrates an example plot of S11 vs. frequency for an example implementation of the present disclosure.

FIG. 7B illustrates an example plot of resonant frequency (fs) vs potential for an example implementation of the present disclosure.

### Example 3

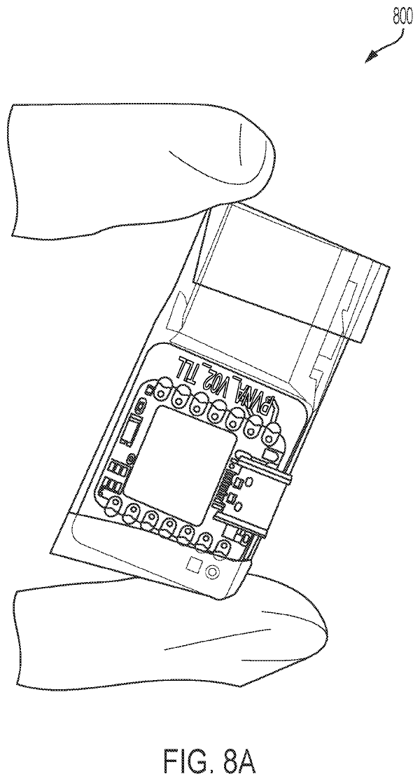

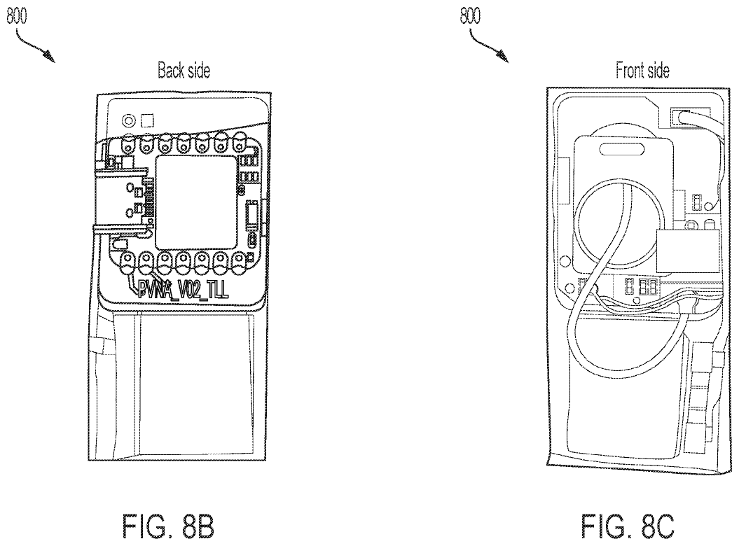

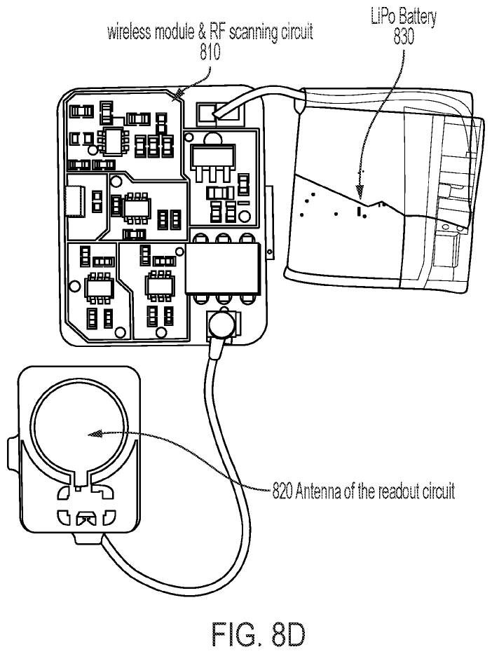

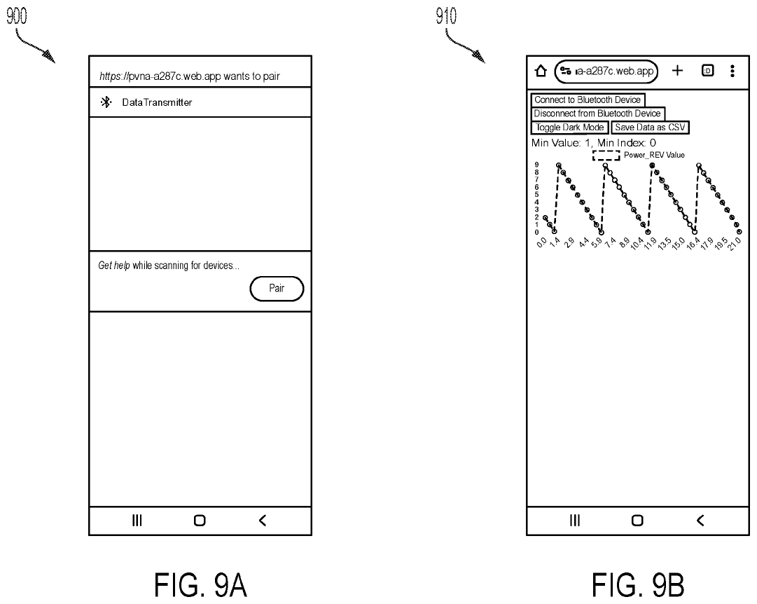

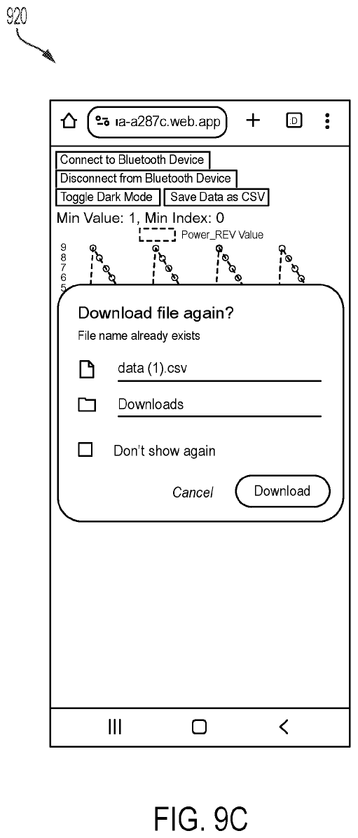

FIGS. 8A-9C illustrate an example implementation of the present disclosure that was designed and tested.

FIG. 8A illustrates a perspective view of a readout circuit 800 according to an example implementation of the present disclosure.

FIG. 8B illustrates a back view of the readout circuit 800 shown in FIG. 8A.

FIG. 8C illustrates a front view of the readout circuit 800 shown in FIG. 8A.

FIG. 8D illustrates a view of a printed circuit board 810 including a wireless module and RF scanning circuit (e.g., the microcontroller 160 and RF scanning circuit 102 shown in FIG. 1), a battery 830, and an antenna 820 used in the readout circuit shown in FIGS. 8A-8D.

Implementations of the present disclosure further include systems and methods for displaying information about the LRC sensor. The information can include the S-parameters, which detail how RF energy behaves within a given component. Alternatively or additionally, the information can include any other measure of signal behavior. Non-limiting examples of information about signal behavior include the phase of the received signal, reflection and/or transmission coefficients, resonance frequency, Q-factor, and/or impedance. As used herein, impedance refers to the LRC sensor's resistance to alternating current. FIGS. 9A-9C illustrate the steps of connecting with the reader, receiving data from the reader, and stores data. It should be understood that an LRC sensor is intended only as a non-limiting example, and that implementations of the present disclosure can be used to measure signal behavior for sensors and electrical components other than LRC sensors.

FIG. 9A illustrates a user interface 900 showing that the display is connected to the reader according to an example implementation of the present disclosure. As shown in FIG. 9A, the connection to the reader can be wireless.

FIG. 9B illustrates a user interface 910 configured to receive data from the reader, according to an example implementation of the present disclosure.

FIG. 9C illustrates a user interface 920 for data storage, according to an example implementation of the present disclosure.

It should be appreciated that the logical operations described herein with respect to the various figures may be implemented (1) as a sequence of computer implemented acts or program modules (i.e., software) running on a computing device (e.g., the computing device described in FIG. 2), (2) as interconnected machine logic circuits or circuit modules (i.e., hardware) within the computing device and/or (3) a combination of software and hardware of the computing device. Thus, the logical operations discussed herein are not limited to any specific combination of hardware and software. The implementation is a matter of choice dependent on the performance and other requirements of the computing device. Accordingly, the logical operations described herein are referred to variously as operations, structural devices, acts, or modules. These operations, structural devices, acts and modules may be implemented in software, in firmware, in special purpose digital logic, and any combination thereof. It should also be appreciated that more or fewer operations may be performed than shown in the figures and described herein. These operations may also be performed in a different order than those described herein.

Referring to FIG. 2, an example computing device 200 upon which the methods described herein may be implemented is illustrated. It should be understood that the example computing device 200 is only one example of a suitable computing environment upon which the methods described herein may be implemented. Optionally, the computing device 200 can be a well-known computing system including, but not limited to, personal computers, servers, handheld or laptop devices, multiprocessor systems, microprocessor-based systems, network personal computers (PCs), minicomputers, mainframe computers, embedded systems, and/or distributed computing environments including a plurality of any of the above systems or devices. Distributed computing environments enable remote computing devices, which are connected to a communication network or other data transmission medium, to perform various tasks. In the distributed computing environment, the program modules, applications, and other data may be stored on local and/or remote computer storage media.

In its most basic configuration, computing device 200 typically includes at least one processing unit 206 and system memory 204. Depending on the exact configuration and type of computing device, system memory 204 may be volatile (such as random access memory (RAM)), non-volatile (such as read-only memory (ROM), flash memory, etc.), or some combination of the two. This most basic configuration is illustrated in FIG. 2 by dashed line 202. The processing unit 206 may be a standard programmable processor that performs arithmetic and logic operations necessary for operation of the computing device 200. The computing device 200 may also include a bus or other communication mechanism for communicating information among various components of the computing device 200.

Computing device 200 may have additional features/functionality. For example, computing device 200 may include additional storage such as removable storage 208 and non-removable storage 210 including, but not limited to, magnetic or optical disks or tapes. Computing device 200 may also contain network connection(s) 216 that allow the device to communicate with other devices. Computing device 200 may also have input device(s) 214 such as a keyboard, mouse, touch screen, etc. Output device(s) 212 such as a display, speakers, printer, etc. may also be included. The additional devices may be connected to the bus in order to facilitate communication of data among the components of the computing device 200. All these devices are well known in the art and need not be discussed at length here.

The processing unit 206 may be configured to execute program code encoded in tangible, computer-readable media. Tangible, computer-readable media refers to any media that is capable of providing data that causes the computing device 200 (i.e., a machine) to operate in a particular fashion. Various computer-readable media may be utilized to provide instructions to the processing unit 206 for execution. Example tangible, computer-readable media may include, but is not limited to, volatile media, non-volatile media, removable media and non-removable media implemented in any method or technology for storage of information such as computer readable instructions, data structures, program modules or other data. System memory 204, removable storage 208, and non-removable storage 210 are all examples of tangible, computer storage media. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In an example implementation, the processing unit 206 may execute program code stored in the system memory 204. For example, the bus may carry data to the system memory 204, from which the processing unit 206 receives and executes instructions. The data received by the system memory 204 may optionally be stored on the removable storage 208 or the non-removable storage 210 before or after execution by the processing unit 206.

It should be understood that the various techniques described herein may be implemented in connection with hardware or software or, where appropriate, with a combination thereof. Thus, the methods and apparatuses of the presently disclosed subject matter, or certain aspects or portions thereof, may take the form of program code (i.e., instructions) embodied in tangible media, such as floppy diskettes, CD-ROMs, hard drives, or any other machine-readable storage medium where, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an application programming interface (API), reusable controls, or the like. Such programs may be implemented in a high level procedural or object-oriented programming language to communicate with a computer system. However, the program(s) can be implemented in assembly or machine language, if desired. In any case, the language may be a compiled or interpreted language and it may be combined with hardware implementations.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A device for measuring a response of a sensor, comprising:
a clock generator configured to transmit a radiofrequency (RF) signal;
an antenna operably connected to the clock generator;
a directional coupler configured to separate the RF signal into an incident wave and a reflected wave;
a peak detector operably connected to the directional coupler; and
a microcontroller operably connected to the peak detector, wherein the microcontroller is configured to measure an output of the peak detector.

2. The device of claim 1, wherein the microcontroller comprises a wireless transceiver, wherein the microcontroller is configured to transmit, using the wireless transceiver, a signal based on a signal received from the peak detector to a remote device.

3. The device of claim 1 or claim 2, wherein the directional coupler comprises a standing wave ratio bridge.

4. The device of any one of claims 1-3, wherein the peak detector is configured to output a DC voltage correlated to an RF power of a signal received from the directional coupler.

5. The device of any one of claims 1-4, wherein the microcontroller is configured to output a resonance frequency of the sensor.

6. The device of any one of claims 1-5, wherein the microcontroller is configured to output an impedance of the sensor.

7. The device of any one of claims 1-6, wherein the microcontroller is configured to output a phase delay of the sensor.

8. The device of any one of claims 1-7, wherein the microcontroller is configured to output a reflection coefficient of the sensor.

9. The device of any one of claims 1-8, wherein the microcontroller is configured to output a transmission coefficient of the sensor.

10. The device of any one of claims 1-9, wherein the microcontroller is configured to output a Q-factor of the sensor.

11. The device of any one of claims 1-10, wherein the microcontroller further comprises an analog to digital converter and the peak detector is operably coupled to the microcontroller via the analog to digital converter.

12. The device of any one of claims 1-11, wherein the microcontroller is operably connected to the clock generator.

13. The device of any one of claims 1-12, wherein the sensor is an inductor-resistor-capacitor (LRC) sensor.

14. The device of any one of claims 1-13, wherein the device is a portable device.

15. A system for measuring a response of a sensor, comprising:
a clock generator configured to transmit a radiofrequency (RF) signal;
an antenna operably connected to the clock generator;
a directional coupler configured to separate the RF signal into an incident wave and a reflected wave;
a peak detector operably connected to the directional coupler; and
a computing device in operable communication with the peak detector, wherein the computing device comprises a processor and a memory, the memory having computer-executable instructions stored thereon that, when executed by the processor, cause the processor to: measure an output of the peak detector.

16. The system of claim 15, wherein the system further comprises a wireless transceiver, wherein the memory has further computer-executable instructions stored thereon that, when executed by the processor, cause the processor to transmit, using the wireless transceiver, a signal based on a signal received from the peak detector to a remote device.

17. The system of claim 15 or claim 16, wherein the directional coupler comprises a standing wave ratio bridge.

18. The system of any one of claims 15-17, wherein the peak detector is configured to output a DC voltage correlated to an RF power of a signal received from the directional coupler.

19. The system of claim any one of claims 15-18, wherein the computing device is configured to output a resonant frequency of the sensor.

20. The system of claim any one of claims 15-19, wherein the computing device is configured to output an impedance of the sensor.

21. The system of claim any one of claims 15-20, wherein the computing device is configured to output a return loss of the sensor.

22. The system of any one of claims 15-21, wherein the computing device further comprises an analog to digital converter and the peak detector is operably coupled to the computing device via the analog to digital converter.

23. The system of any one of claims 15-22, wherein the computing device is operably connected to the clock generator.

24. The system of any one of claims 15-23, wherein the sensor is configured to monitor properties including, but not limited to, phase delay, reflection and transmission coefficients, resonance frequency, Q-factor, and impedance.

25. The system of any one of claims 15-24, wherein the sensor is an inductor-resistor-capacitor (LRC) sensor.

26. The system of any one of claims 15-25, wherein the system is a portable device.

27. The system of any one of claims 15-26, wherein the system is a miniaturized wired device.
